(19) United States
(12) Patent Application Publication
(10) Pub. No.: US 2025/0125178 A1
(43) Pub. Date: Apr. 17, 2025

(54) METHOD OF TRANSFERRING TARGET OBJECT TO TARGET SUBSTRATE

(71) Applicant: Innolux Corporation, Miaoli County (TW)

(72) Inventors: Chen-Lin Yeh, Miaoli County (TW); Yan-Zheng Wu, Miaoli County (TW)

(73) Assignee: Innolux Corporation, Miaoli County (TW)

(21) Appl. No.: 18/830,572

(22) Filed: Sep. 10, 2024

Related U.S. Application Data
(60) Provisional application No. 63/543,515, filed on Oct. 11, 2023.

(30) Foreign Application Priority Data
Jun. 18, 2024 (CN) 202410787446.7

(51) Int. Cl. H01L 21/68; H01L 21/67; H01L 21/687

(52) U.S. Cl. CPC H01L 21/68; H01L 21/67259; H01L 21/68764

(57) ABSTRACT

Disclosed is a method of transferring a target object to a target substrate including the following steps; first, defining a plurality of units recurring on the target substrate, wherein one of the plurality of units is made up of a plurality of target locations on the target substrate; next, disposing the plurality of target objects on a unit transfer stamp, wherein the plurality of target objects on the unit transfer stamp correspond to the plurality of target locations; afterwards, transferring the plurality of target objects to the target substrate using the unit transfer stamp; then, transferring at least one target object to the remaining target locations on the target substrate.

### CROSS-REFERENCE TO RELATED APPLICATION

This application claims the priority benefit of U.S. provisional application Ser. No. 63/543,515, filed on Oct. 11, 2023, and China application serial no. 202410787446.7, filed on Jun. 18, 2024. The entirety of each of the above-mentioned patent applications is hereby incorporated by reference herein and made a part of this specification.

### BACKGROUND

### Field of the Disclosure

The present disclosure relates to a method of transferring a target object to a target substrate, and in particular, to a method of transferring a control element to a circuit substrate.

### Description of Related Art

When transferring a control element to a circuit substrate to control antenna units on the circuit substrate, if there are a relatively large number of antenna units and/or multiple antenna units are arranged on the circuit substrate irregularly, the efficiency of the transfer process will be low.

### SUMMARY OF THE DISCLOSURE

Some embodiments of the present disclosure are directed to a method of transferring a target object to a target substrate, which may improve the efficiency of transferring the target object to the target substrate.

According to some embodiments of the present disclosure, a method for transferring a target object to a target substrate includes the following steps: first of all, defining a plurality of units recurring on the target substrate, wherein one of the plurality of units is made up of a plurality of target locations on the target substrate; next, disposing the plurality of target objects on a unit transfer stamp, wherein the plurality of target objects on the unit transfer stamp correspond to the plurality of target locations; then, transferring the plurality of target objects to the target substrate using the unit transfer stamp; finally, transferring at least one target object to the remaining target locations on the target substrate.

According to other embodiments of the present disclosure, a method for transferring a target object to a target substrate includes the following steps: first, defining a plurality of first units and a plurality of second units recurring on the target substrate, wherein one of the plurality of first units is made up of a plurality of first target locations on the target substrate, and one of the plurality of second units is made up of a plurality of second target locations on the target substrate; next, disposing a plurality of target objects on a first unit transfer stamp, wherein the plurality of target objects on the first unit transfer stamp correspond to a plurality of first target locations; then, transferring the plurality of target objects to the target substrate using the first unit transfer stamp; then, disposing the plurality of target objects on the second unit transfer stamp, wherein the plurality of target objects on the second unit transfer stamp correspond to a plurality of second target locations; finally, transferring the plurality of target objects to the target substrate using the second unit transfer stamp.

Based on the above, in the method for transferring a target object to a target substrate provided by the present disclosure, by defining a recurring unit made up of a plurality of target locations on the target substrate, and disposing the target object on the unit transfer stamp in the form of units, it is possible to improve the efficiency of transferring the target object to the target substrate.

In order to make the above-mentioned features and advantages of the present disclosure more clear and understandable, embodiments are given below and described in detail with reference to the accompanying drawings.

### BRIEF DESCRIPTION OF THE DRAWINGS

FIG. 1A is a schematic top view of a target substrate according to the first embodiment of the present disclosure.

FIG. 1B is a schematic top view of a target object according to an embodiment of the present disclosure.

FIG. 1C is a schematic top view of the target substrate of FIG. 1A divided into multiple regions.

FIG. 1D is a schematic top view of a unit transfer stamp according to an embodiment of the disclosure.

FIG. 2A is a schematic top view of a target substrate according to the second embodiment of the present disclosure.

FIG. 2B is a schematic view of multiple line segments on the target substrate of FIG. 2A.

FIG. 2C is a schematic top view of various embodiments in which the target object is disposed on the unit transfer stamp.

FIG. 3A is a schematic top view of the target substrate according to the third embodiment of the present disclosure, which shows a schematic top view of the unit in the first embodiment in the target substrate.

FIG. 3B is a schematic top view of the unit in the second embodiment of the target substrate of FIG. 3A.

FIG. 3C is a schematic top view of the unit in the third embodiment of the target substrate of FIG. 3A.

FIG. 3D is a schematic top view of the unit in the fourth embodiment of the target substrate of FIG. 3A.

FIG. 4A is a schematic top view of a target substrate according to the fourth embodiment of the present disclosure, which shows a schematic top view of a unit in the first embodiment of the target substrate.

FIG. 4B is a schematic top view of the unit in the second embodiment of the target substrate of FIG. 4A.

FIG. 4C is a schematic top view of the unit in the third embodiment of the target substrate of FIG. 4A.

FIG. 4D is a schematic top view of the unit in the fourth embodiment of the target substrate of FIG. 4A.

FIG. 5A is a schematic top view of a target substrate according to the fifth embodiment of the present disclosure, which shows a schematic top view of a unit in the first embodiment of the target substrate.

FIG. 5B is a schematic top view of the unit in the second embodiment of the target substrate of FIG. 5A.

FIG. 5C is a schematic top view of the unit in the third embodiment of the target substrate of FIG. 5A.

FIG. 5D is a schematic top view of the unit in the fourth embodiment of the target substrate of FIG. 5A.

FIG. 6A is a schematic top view of a target substrate according to the sixth embodiment of the present disclosure.

FIG. 6B is a top view of a target object according to another embodiment of the present disclosure.

FIG. 7A is a schematic top view of a target substrate according to the seventh embodiment of the present disclosure, which shows a schematic top view of a unit in the first embodiment of the target substrate.

FIG. 7B is a schematic top view of the unit in the second embodiment of the target substrate of FIG. 7A.

### DESCRIPTION OF EMBODIMENTS

Reference will now be made in detail to the exemplary embodiments of the present disclosure, examples of which are illustrated in the accompanying drawings. Wherever possible, the same reference numbers are used in the drawings and descriptions to refer to the same or like parts.

The disclosure may be understood by referring to the following detailed description with reference to the accompanying drawings. It is noted that for comprehension of the reader and simplicity of the drawings, in the drawings of the disclosure, only a part of the electronic device is shown, and specific elements in the drawings are not necessarily drawn to scale. Moreover, the quantity and the size of each element in the drawings are only schematic and are not intended to limit the scope of the disclosure.

Certain terms will be used throughout the specification and appended claims of this disclosure to refer to particular elements. Those skilled in the art should understand that electronic device manufacturers may refer to the same element by different names. The text does not intend to distinguish between those elements that have the same function but have different names. In the following description and claims, terms such as “comprising”, “including”, and “having” are open-ended words, so they should be interpreted as meaning “including but not limited to . . . ”. Therefore, when the terms “comprises,” “containing,” and/or “having” are used in the description of the present disclosure, they specify the presence of the corresponding features, regions, steps, operations, and/or elements, but do not exclude the presence of one or more corresponding features, regions, steps, operations and/or elements.

The directional terms mentioned herein, such as “upper”, “lower”, “front”, “rear”, “left”, “right”, etc., only refer to the directions of the accompanying drawings. Accordingly, the directional terms are used for illustration, not for limitation of the present disclosure. In the drawings, each figure illustrates the general characteristics of methods, structures and/or materials used in particular embodiments. However, these drawings should not be interpreted as defining or limiting the scope or nature encompassed by these embodiments. For example, the relative sizes, thicknesses and positions of layers, regions and/or structures may be reduced or exaggerated for clarity.

When a corresponding member (such as a layer or a region) is described as being “on another member,” it may be directly on another member, or there may be other member therebetween. On the other hand, when a member is described as being “directly on another member,” no member exists therebetween unless specifically defined in the specification. In addition, when a member is described as being “on another member,” the two have a vertical relationship in the top view direction, and this member may be located above or below the other member, and the vertical relationship depends on the device orientation.

The terms “equal to” or “same”, and “essentially” or “substantially” are generally interpreted as within 20% of a given value or range, or as within 10%, 5%, 3%, 2%, 1%, or 0.5% of the value or range.

Ordinal numbers in this specification and the claims such as “first” and “second” are used to modify an element, and do not imply or represent that the (or these) element(s) has (or have) any ordinal number, and do not indicate any order between an element and another element, or an order in a manufacturing method. These ordinal numbers are merely used to clearly distinguish an element having a name with another element having the same name. Different terms may be used in the claims and the specification, so that a first member in the specification may be a second member in the claims.

It should be understood that the following embodiments may disassemble, replace, reorganize, and mix the features in several different embodiments to complete other embodiments without departing from the spirit of the disclosure. As long as the features of the embodiments do not violate the spirit of the disclosure or conflict each other, they may be mixed and matched as desired.

Electrical connection or coupling described in the disclosure may refer to direct connection or indirect connection. In the case of direct connection, terminals of elements on two circuits are directly connected or connected to each other by a conductor segment. In the case of indirect connection, there is a switch, a diode, a capacitor, an inductor, a resistor, other suitable elements, or a combination of the above elements between the terminals of the elements on the two circuits, but not limited thereto.

In the disclosure, the thickness, length, width, and area may be measured by an optical microscope, and the thickness may be measured from a cross-sectional image in an electron microscope, but it is not limited thereto. In addition, a certain error may be provided between any two values or directions used for comparison. If the first value is equal to the second value, it implies that an error of approximately 10% is provided between the first value and the second value. If the first direction is perpendicular to the second direction, the angle between the first direction and the second direction may be between 80 degrees and 100 degrees. If the first direction is parallel to the second direction, the angle between the first direction and the second direction may be between 0 degrees and 10 degrees.

The electronic device described in the present disclosure may be applied to a display device, a light-emitting device, a backlight device, an antenna device, a sensing device or a splicing device, or a temporary storage substrate used to assist electronic units to be disposed at a specific distance. However, the disclosure is not limited thereto. The electronic device may be a bendable or flexible electronic device. A display device may be a non-self-luminous display device or a self-luminous display device. The antenna device may be a liquid crystal type antenna device or a non-liquid crystal type antenna device, and the sensing device may be a sensing device that senses capacitance, light, heat energy or ultrasonic waves, but the disclosure is not limited thereto. Electronic devices may include electronic elements such as passive elements and active elements, such as capacitors, resistors, inductors, diodes, transistors, etc. Diodes may include light-emitting diodes or photodiodes. Light-emitting diodes (LEDs) may include, for example, organic light-emitting diodes (OLEDs), mini light-emitting diodes (mini LEDs), micro light-emitting diodes (micro LEDs), or quantum dot light-emitting diodes (QDLEDs), but the disclosure is not limited thereto. The splicing device may be, for example, a display splicing device or an antenna splicing device, but the disclosure is not limited thereto. It should be noted that the electronic device may be arranged in any combination of the above, but the disclosure is not limited thereto. In addition, a shape of the electronic device may be rectangular, circular, polygonal, shaped with curved edges, or other suitable shapes.

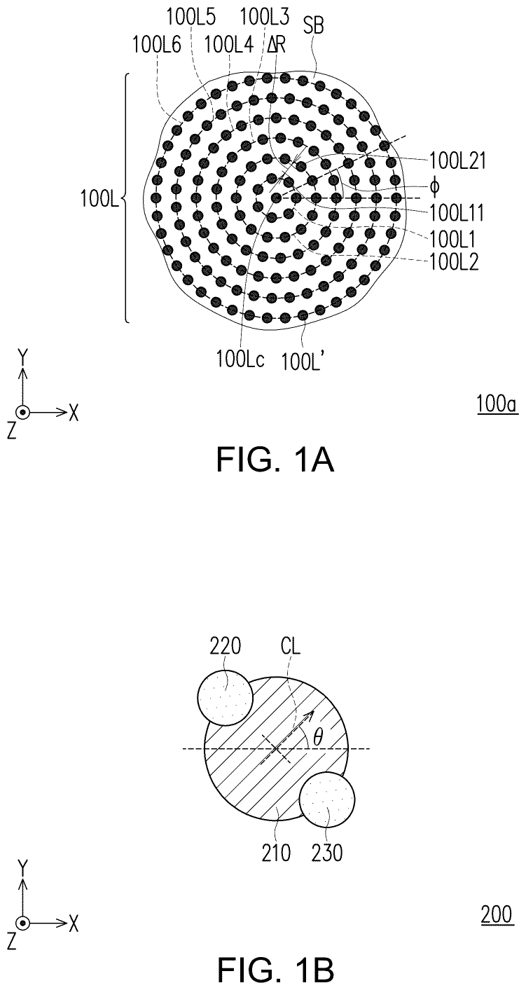

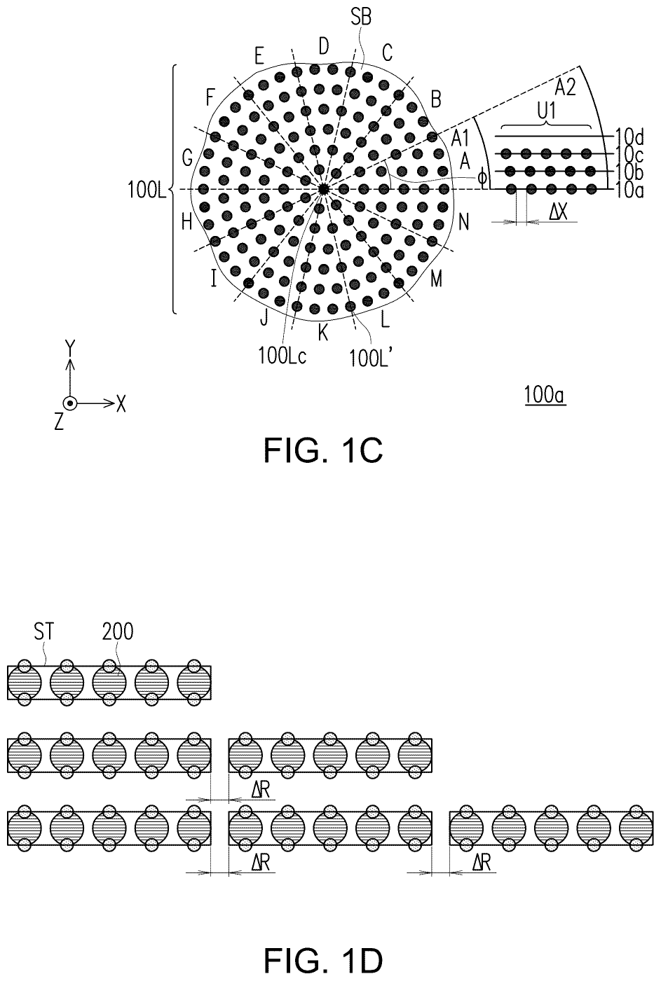

FIG. 1A is a schematic top view of a target substrate according to the first embodiment of the present disclosure. FIG. 1B is a schematic top view of a target object according to an embodiment of the present disclosure.

Please refer to FIG. 1A, which shows a target substrate 100a. In this embodiment, the target substrate 100a includes a target location 100L where a plurality of target objects 200 are to be disposed. The target substrate 100a may be, for example, a circuit substrate. For example, the target substrate 100a may include a base SB and an element layer (not shown).

The material of the base SB may be, for example, glass, plastic or a combination thereof. For example, the material of the base SB may include quartz, sapphire, silicon (Si), germanium (Ge), silicon carbide (SiC), gallium nitride (GaN), silicon germanium (SiGe), polymethyl methacrylate (PMMA), polycarbonate (PC), polyimide (PI), polyethylene terephthalate (PET) or other suitable materials or a combination of the above materials, this disclosure is not limited thereto.

The element layer is, for example, disposed on the base SB, and may, for example, include electrical connection structures (not shown) and electronic elements (not shown).

The electrical connection structure may, for example, include at least one conductive layer and at least one insulating layer that are alternately stacked with each other, wherein two adjacent conductive layers may be electrically connected to each other through openings in the insulating layer therebetween, so that the electrical connection structure may serve as a conductive transmission path.

For example, the electronic element is disposed on the electrical connection structure and is electrically connected thereto. In some embodiments, the electronic elements may include antenna elements, light-emitting elements, or other suitable electronic elements. In this embodiment, the electronic elements include reconfigurable intelligent surface (RIS) elements, frequency selective surface (FSS) elements, orbital angular momentum (OAM) elements, and other antenna elements or a combination thereof, but this disclosure is not limited thereto.

A target object 200 may include, for example, another electronic element. In this embodiment, the target object 200 includes control elements used to control the above-mentioned electronic elements. For example, the target object 200 may include switching elements, light-emitting diodes, varactor diodes, or other suitable control elements, but the disclosure is not limited thereto. Please refer to FIG. 1B, which shows a top view of the target object 200. In this embodiment, the target object 200 includes a chip 210 and pads 220 and 230 disposed on the chip 210 in the direction Z. For example, the pads 220 and 230 are disposed corresponding to the line segment CL passing through the center of the chip 210. It is worth noting that this embodiment defines the rotation angle θ of the target object 200 as the angle between the line segment CL passing through the center of the chip 210 and the direction X.

In some embodiments, the plurality of target objects 200 each include the same chip, but the disclosure is not limited thereto. In other embodiments, the plurality of target objects 200 may each include different chips.

In some embodiments, the shapes of the plurality of target objects 200 may each include a circle, a rectangle, a hexagon or a hexagon. In other words, each of the plurality of target objects 200 may have different sizes and/or shapes, but the disclosure is not limited thereto.

In this embodiment, in order to utilize the transfer stamp to transfer the plurality of target objects 200, it is necessary to first define the setting relationship between the plurality of target locations 100L on the target substrate 100a to design a form of the unit transfer stamp, whereby the efficiency of transferring the target object 200 may be increased by performing repeated actions (such as translation or rotation) on the unit transfer stamp. After transferring most of the target objects 200 using the unit transfer stamp, smaller unit transfer stamps or a single transfer unit may be utilized to transfer individual target objects 200 to the remaining target locations 100L respectively. In the above concept proposed in this embodiment, the transfer process may be divided into two stages: (1) sampling; (2) repetition. (1) Sampling refers to finding a unit made up of a plurality of target locations 100L, and translating or rotating the unit to find the same recurring unit on the target substrate 100a. It is worth noting that the recurring units refer to the remaining multiple target locations 100L that may utilize the unit transfer stamp to transfer the target object 200 through translation or rotational symmetry.

Although changing the location of the target object 200 may affect the efficiency of the electronic device (not shown) including the target object 200, the problem may be overcome by the following means: (1) increasing the density of the target object 200; (2) performing compensation through other electronic elements (e.g., active elements such as power amplifiers or phase detectors); (3) applying the electronic device including the target object 200 to the fields with relatively low requirements on efficiency.

Please continue to refer to FIG. 1A. In this embodiment, the central angle q between the line connecting any target location 100L′ on the target substrate 100a and the central location 100Lc is related to the central location 100Lc, but the central angle φ between the line connecting any target location 100L′ on the target substrate 100a and the central location 100Lc is irrelevant to the rotation angle θ of the target object 200, more details will be described in the following embodiments.

In this embodiment, the target locations 100L of the target substrate 100a are disposed in a symmetrical radial arrangement. In detail, the target location 100L includes the central location 100Lc and the remaining target locations 100L′. The remaining target locations 100L′ are, for example, arranged away from the central location 100Lc, and the remaining target locations 100L′ with substantially equal distance from the central location 100Lc may be arranged in a circle. In this embodiment, the remaining target locations 100L′ include the first circle of target locations 100L1, the second circle of target locations 100L2, the third circle of target locations 100L3, the fourth circle of target locations 100L4, the fifth circle of target locations 100L5 and the sixth circle of target locations 100L6 arranged away from the central location 100Lc in the sequence described above, and the target location increases by the same amount. For example, the first circle of target locations 100L1 may include n target locations, the second circle of target locations 100L2 may include 2*n target locations, the third circle of target locations 100L3 may include 3*n target locations, and the number of target locations of the fourth circle of target locations 100L4, the fifth circle of target locations 100L5, and the sixth circle of target locations 100L6 may be deduced in this way. In this embodiment, there is a distance ΔR (for example, the distance between target location 100L11 and target location 100L21 shown in FIG. 1A) between target locations in adjacent circles. Since the target locations 100L are arranged in a symmetrical radial arrangement, the target substrate 100a may be divided into a plurality of regions having recurring units.

FIG. 1C is a schematic top view of the target substrate of FIG. 1A divided into multiple regions.

Please refer to FIG. 1C, which shows that the target substrate 100a is divided into a region A, a region B, a region C, a region D, a region E, a region F, a region G, a region H, a region I, a region J, a region K, a region L, a region M and a region N, wherein the above regions have the same central angle φ. It is worth mentioning that the central angle φ is calculated with the central location 100Lc as the center of the circle. Based on this, the central angle φ of each region of the target substrate 100a may be 360/(2*n) degrees, but the disclosure is not limited thereto. In this embodiment, the regions A to N may be further divided into a first region and a second region. Taking the region A as an example, the region A is divided into a first region A1 and a second region A2. The first region A1 refers to, for example, that the target location 100L has less repetitively arranged features in this region. For example, the distances between adjacent target locations 100L in the first region A1 are significantly different, or the target locations 100L are not arranged in a straight line. The second region A2, for example, refers to that the target locations 100L have sequentially arranged features in this region, wherein the sequentially arranged features may include, for example, multiple groups of adjacent target locations 100L with the same distance and/or multiple groups of target locations 100L arranged in a straight line.

In the second region A2, the arrangement of the target locations 100L on the same straight line (for example, the straight line 10a, the straight line 10b, the straight line 10c and the straight line 10d extending in the direction X) having the following features may be regarded as a sequential arrangement: (1) The difference between each distance ΔX between adjacent target locations 100L on a straight line and the distance ΔR between target locations in adjacent circles is less than 0.01 mm; (2) The maximum height difference (difference of components in direction Y) between target locations 100L on a straight line is less than 0.03 mm.

In detail, please refer to FIG. 1C, taking the straight line 10a as an example. The five target locations 100L on the straight line 10a satisfy the above features, so they may form a unit U1. However, the unit U1 is not limited to including only five target locations 100L. After determining the unit U1 on the target substrate 100a, the target object 200 may be disposed on the unit transfer stamp ST as shown in FIG. 1D in the form of unit U1. Subsequently, the target object 200 may be transferred onto the straight line 10a of the target substrate 100a through the unit transfer stamps ST. It is worth noting that, please refer to FIG. 1D, the unit transfer stamps ST may be designed in multiple and have a distance ΔR between each other, thereby improving the efficiency of transferring the target object 200 to the target substrate 100a. Please continue to refer to FIG. 1C. After finding the unit U1 on the straight line 10a, with regard to the five target locations 100L on the straight line 10b and the straight line 10c, the difference between them and the five target locations 100L on the straight line 10a lies only in the starting point of the of the target locations 100L in the direction X. In this way, the target object 200 may be sequentially transferred to the straight line 10b and the straight line 10c of the target substrate 100a by utilizing a transfer device (not shown) to sequentially translate the unit transfer stamp ST by a specific distance in the direction Y and the direction X respectively. Based on the above, the configuration of the target object 200 in the second region A2 may be completed by repeating the above steps.

With regard to the first region A1 of region A, for example, a single target object 200 may be sequentially transferred to the remaining target locations 100L; or another unit that may exist in the first region A1 may be found, and the plurality of target objects 200 are transferred to the remaining target locations 100L in sequence in the steps described in the above embodiment.

With regard to region B, the unit U1 may also be found in their respective second regions. The difference between region B and region A is that the line segment CL at the center of the chip 210 to be disposed in the region B has a rotation angle θ with 360/(2*n) degrees. Therefore, the target object 200 may be transferred to the second region of the region B by rotating the transfer stamp ST by an angle of 360/(2*n) degrees using a transfer device (not shown).

With regard to region C to region N, the target object 200 may also be transferred through the steps described in the above embodiment, which will not be described again.

Based on the above, by dividing a plurality of regions (region A to region N) having a central angle φ of 360/(2*n) degrees, and further dividing each of the plurality of regions into a first region and a second region, it is possible to increase the efficiency of transferring the target object 200 to the target substrate 100a.

Through the description of the above embodiments, the method of transferring the target object 200 to the target substrate 100a in this embodiment includes the following steps.
Step (1): A plurality of units U1 recurring on the target substrate 100a are defined, wherein one of the plurality of units U1 is made up of a plurality of target locations 100L on the target substrate 100a.
Step (2): A plurality of target objects 200 are disposed on the unit transfer stamp ST, wherein the plurality of target objects 200 on the unit transfer stamp ST correspond to a plurality of target locations 100L.
Step (3): The unit transfer stamp ST is utilized to transfer the plurality of target objects 200 to the target substrate 100a.

In this step, the unit transfer stamp ST may be utilized to transfer the first group of target objects 200 to the first region on the target substrate 100a (for example, a region made up of the plurality of target locations 100L through which the straight line 10a passes). Thereafter, the unit transfer stamp ST is moved in the direction X and/or direction Y. After the unit transfer stamp ST is attached to the second group of target objects 200, the unit transfer stamp ST is utilized to transfer the second group of target objects 200 to a second region (for example, a region made up of the plurality of target locations 100L through which the straight line 10b passes) on the target substrate 100a. However, the disclosure is not limited thereto.
Step (4): At least one target object 200 is transferred to the remaining target locations on the target substrate 100a.

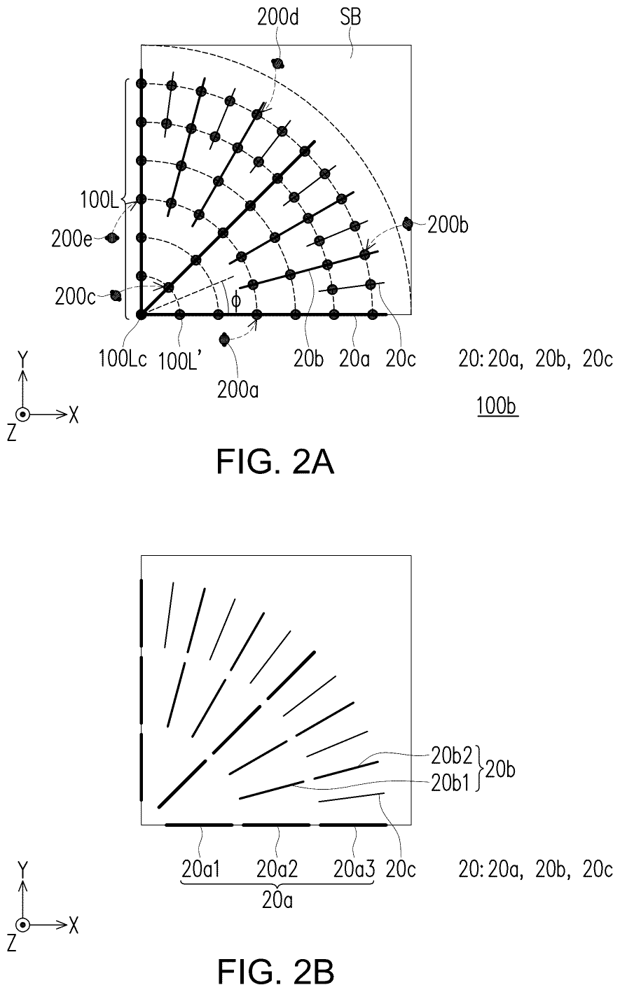

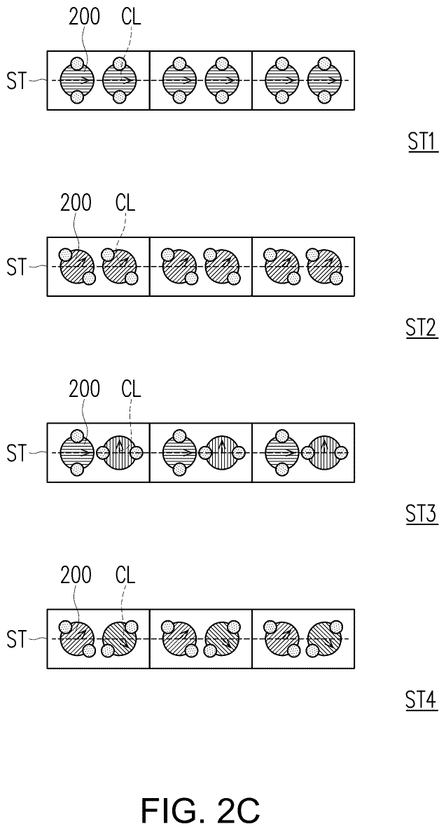

FIG. 2A is a schematic top view of a target substrate according to the second embodiment of the present disclosure, and FIG. 2B is a schematic view of multiple line segments on the target substrate of FIG. 2A. It should be noted that the embodiment of FIG. 2A may adopt the component numbers and part of the content of the embodiment of FIG. 1A, wherein the same or similar numbers are adopted to represent the same or similar components, and descriptions of the same technical content are omitted.

Please refer to FIG. 2A, which shows a target substrate 100b. In this embodiment, the central angle φ between the line connecting any target location 100L′ on the target substrate 100b and the central location 100Lc is related to the central location 100Lc, and the central angle φ between the line connecting the target location 100L on the target substrate 100b and the central location 100Lc is also related to the rotation angle θ of the target object 200. Under the circumstances, a plurality of straight lines 20 may be found in the radial direction passing through the central location 100Lc, wherein the straight lines 20 pass through the centers of the plurality of target locations 100L.

For example, in this embodiment, a plurality of straight lines 20a, a plurality of straight lines 20b, and a plurality of straight lines 20c may be found on the target substrate 100b. There are six target locations 100L on the straight lines 20a, there are four target locations 100L on the straight lines 20b, and there are two target locations 100L on the straight lines 20c, but the disclosure is not limited thereto. In some embodiments, after finding the plurality of straight lines 20a, the plurality of straight lines 20b, and the plurality of straight lines 20c, it is possible to further find the greatest common factor of the number of target locations 100L on the straight lines. Please refer to FIG. 2B. In this embodiment, the greatest common factor of the number of target locations 100L on the plurality of straight lines 20a, the plurality of straight lines 20b, and the plurality of straight lines 20c is 2. Afterwards, each of the plurality of straight lines 20a, the plurality of straight lines 20b and the plurality of straight lines 20c may be further divided into a plurality of line segments based on the above-mentioned greatest common factor. In detail, the plurality of straight lines 20a may be further divided into line segments 20a1, 20a2, and 20a3, and the plurality of straight lines 20b may be further divided into line segments 20b1 and 20b2. The target locations 100L on the plurality of straight lines 20c is the same as the above-mentioned greatest common factor and does not need to be further divided. Thereafter, the manner in which the target object 200 is disposed on the unit transfer stamp ST may be determined.

FIG. 2C is a schematic top view of various embodiments in which the target object is disposed on the unit transfer stamp.

Taking the straight lines 20a as an example, the six target objects 200 to be disposed on the six target locations 100L of the straight lines 20a may have similar rotation angles θ therebetween or may be classified into a plurality of groups with similar rotation angles θ. For example, please refer to FIG. 2C, six target objects 200 are disposed on the transfer stamp ST1 with a rotation angle θ of 0 degrees; or the six target objects 200 are disposed on the transfer stamp ST2 with a rotation angle θ of 45 degrees. In other embodiments, the six target objects 200 may be classified into three groups of target object units with rotation angles θ of 0 degrees and 90 degrees and disposed on the transfer stamp ST3. In some other embodiments, the six target objects 200 may be classified into three groups of target object units with rotation angles θ of 45 degrees and −45 degrees and are disposed on the transfer stamp ST4. It is worth noting that each of transfer stamp ST1, transfer stamp ST2, transfer stamp ST3 and transfer stamp ST4 includes three unit transfer stamps ST. In addition, any one of transfer stamp ST1, transfer stamp ST2, transfer stamp ST3 and transfer stamp ST4 may also be used as a unit transfer stamp, and the present disclosure is not limited thereto.

Please continue to refer to FIG. 2A. After determining the manner in which the target object 200 is disposed on the unit transfer stamp ST, taking the transfer stamp ST1 as an example, the transfer device (not shown), for example, may first be used to transfer the target object 200 through the transfer stamp ST1 on the straight line 20a with the central angle φ being 0 degrees. Then, after using the transfer device to rotate the above-mentioned transfer stamp ST1 by 45 degrees (or using a platform (not shown) to rotate the target substrate 100b by −45 degrees) and/or translating the transfer stamp ST1 by a specific distance, the target object 200 is transferred on the straight line 20a with the central angle q being 45 degrees. Subsequently, the transfer of the target object 200 on the target location 100L of the straight line 20a may be completed based on the above steps, and related details will not be described again.

With regard to the four target locations 100L on the straight lines 20b, the transfer of the target object 200 on the target location 100L on the straight line 20b may be completed by combining the two unit transfer stamps ST to form a transfer stamp for performing the above steps, and related details are not described again.

With regard to the two target locations 100L on the straight lines 20c, the above steps may be performed by utilizing one unit transfer stamp ST to complete the transfer of the target object 200 on the target location 100L on the straight line 20c, and related details will not be described again.

Although not shown in FIG. 2A, for the target locations 100L that are not passed through by the straight lines 20, each of the target objects 200 may, for example, be sequentially transferred to the predetermined target location 100L.

Through the description of the above embodiments, the method of transferring the target object 200 to the target substrate 100b in this embodiment includes the following steps.
Step (1): A plurality of units (for example, multiple straight lines 20a) recurring on the target substrate 100b are defined, wherein one of the plurality of units is made up of a plurality of target locations (for example, six target locations 100L on the straight lines 20a) on the target substrate 100b.
Step (2): A plurality of target objects 200 are disposed on the unit transfer stamp (e.g., transfer stamp ST1), wherein the plurality of target objects 200 on the unit transfer stamp correspond to the plurality of target locations 100L.
Step (3): The unit transfer stamp is utilized to transfer the plurality of target objects 200 to the target substrate 100b.

In this step, the first group of target objects 200 may be transferred to the first region (for example, the region made up of six target locations 100L through which the straight line 20a passes) on the target substrate 100b using the transfer stamp ST1, and then the transfer stamp ST1 is rotated by a specific angle (for example, 45 degrees) or the target substrate 100b is rotated by a specific angle (for example, −45 degrees). After the transfer stamp ST1 is attached to the second group of target objects 200, the transfer stamp ST1 is utilized to transfer the second group of target objects 200 to the second region (for example, the region made up of six target locations 100L through which another straight line 20a passes) on the target substrate 100b. However, this disclosure is not limited thereto.
Step (4): The at least one target object 200 is transferred to the remaining target locations of the target substrate 100b.

However, the method of transferring the target object 200 to the target substrate 100b is not limited thereto. Another embodiment of the method of transferring the target object 200 to the target substrate 100b in this embodiment includes the following steps.
Step (1′): A plurality of first units (for example, multiple straight lines 20a) and a plurality of second units (for example, multiple straight lines 20b or multiple straight lines 20c) recurring on the target substrate 100b are defined, wherein one of the plurality of first units is made up of a plurality of first target locations (e.g., six target locations 100L on the straight line 20a) on the target substrate 100b, and one of the plurality of second units is made up of a plurality of second target locations (for example, four target locations 100L on the straight line 20b or two target locations 100L on the straight line 20c) on the target substrate 100b.
Step (2a): A plurality of target objects 200 are disposed on the first transfer stamp (for example, the transfer stamp ST1 made up of three unit transfer stamps ST), wherein the plurality of target objects 200 on the first transfer stamp correspond to the plurality of first target locations (for example, six target locations 100L on the straight line 20a).
Step (3a): The first transfer stamp is utilized to transfer the plurality of target objects 200 to the plurality of first target locations (for example, six target locations 100L on the straight line 20a) on the target substrate 100b.
Step (2b): The plurality of target objects 200 are disposed on the second transfer stamp (for example, a transfer stamp made up of two unit transfer stamps ST or a unit transfer stamp ST), wherein the plurality of target objects 200 on the second transfer stamp correspond to the plurality of second target locations (for example, four target locations 100L on the straight line 20b or two target locations 100L on the straight line 20c).
Step (3b): The second transfer stamp is utilized to transfer the plurality of target objects 200 to the plurality of second target locations (for example, four target locations 100L on the straight line 20b or two target locations 100L on the straight line 20c) on the target substrate 100b.
Step (4): At least one target object 200 is transferred to the remaining target locations of the target substrate 100b.

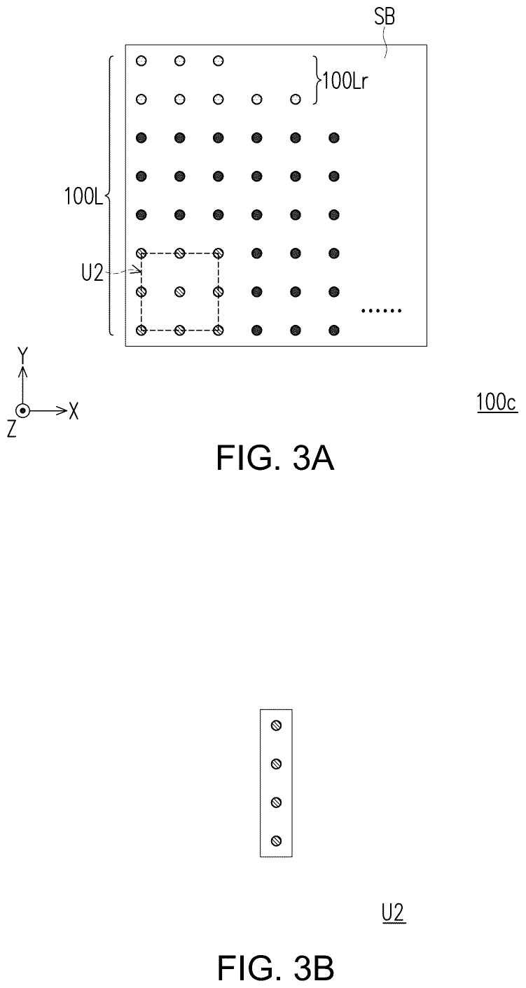

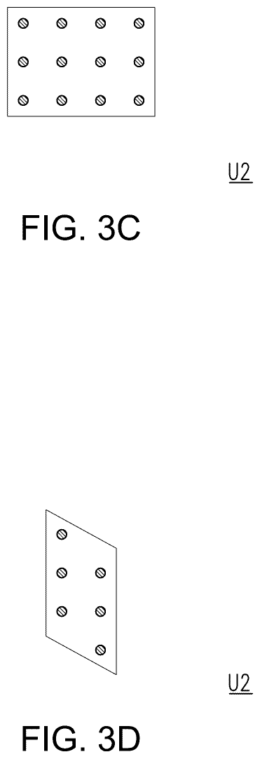

FIG. 3A is a schematic top view of the target substrate according to the third embodiment of the present disclosure, which shows a schematic top view of the unit in the first embodiment in the target substrate. FIG. 3B is a schematic top view of the unit in the second embodiment of the target substrate of FIG. 3A. FIG. 3C is a schematic top view of the unit in the third embodiment of the target substrate of FIG. 3A. FIG. 3D is a schematic top view of the unit in the fourth embodiment of the target substrate of FIG. 3A. It should be noted that the embodiments of FIG. 3A to FIG. 3D may respectively adopt the component numbers and part of the content of the embodiments of FIG. 1A and FIG. B, wherein the same or similar numbers are used to represent the same or similar elements, and description of the same technical content is omitted.

Referring to FIG. 3A, the distribution of target locations 100L on the target substrate 100c is irrelevant with the rotation angle θ of the target object 200. However, the distribution of target objects 200 in this embodiment satisfies translational symmetry, so a relatively small unit U2 made up of the plurality of target locations 100L may be found on the target substrate 100c. After the target object 200 is disposed on the unit transfer stamp (not shown) in the form of the unit U2, the stamp may be utilized repeatedly to transfer the plurality of target objects 200 to the target substrate 100c, thereby improving the efficiency of transferring the target object 200 to the target substrate 100c.

In this embodiment, the distribution of target object 200 has the following relationships:

$$\begin{matrix}{Die}_{A} ∈ {Unit}_{A} ; \\ {Unit}_{A} ( {r}_{o} + R ) = {Unit}_{A} ( {r}_{o} ) ,\end{matrix}$$

wherein Die is the target object 200, Unit_{A} is the unit U2 made up of a plurality of target locations 100L, rₒ is the starting location of the unit U2, and R is the translation amount of the unit U2.

Specifically, in this embodiment, please refer to FIG. 1B, the rotation angle θ of each target object 200 to be disposed on the target substrate 100c is 45 degrees or a different angle. Under the circumstances, it is possible to find the unit U2 made up of a plurality of target locations 100L on the target substrate 100c. Please continue to refer to FIG. 3A, which shows that the unit U2 is a rectangular pattern made up of 3×3 target locations 100L. Based on the above, the target object 200 may be disposed on the unit transfer stamp (not shown) in the form of the above-mentioned unit U2, and then 3×3 target objects 200 may be transferred to the recurring unit U2 of the target substrate 100c through the unit transfer stamp, thereby improving the efficiency of transferring the target object 200 to the target substrate 100c.

However, this disclosure does not limit that the unit U2 is made up of 3×3 target locations 100L. Please refer to FIG. 3B to FIG. 3D respectively. The unit U2 may be, for example, a rectangular pattern made up of 1×4 target locations 100L; or the unit U2 may be, for example, a rectangular pattern made up of 4×3 target locations 100L; or the unit U2 may be, for example, a diamond pattern made up of 2×3 target locations 100L.

Please continue to refer to FIG. 3A. After the plurality of target objects 200 are transferred to the recurring unit U2 on the target substrate 100c, for the target locations 100L of the non-recurring units on the target substrate 100c, a single target object 200 may be, for example, respectively transferred sequentially to the target locations 100L of the non-recurring units, but the present disclosure is not limited thereto. In other embodiments, the target locations 100L of the non-recurring units may be divided into smaller units (smaller than unit U2), and the target object 200 is transferred to the remaining target locations 100Lr of the target substrate 100c by performing the above steps.

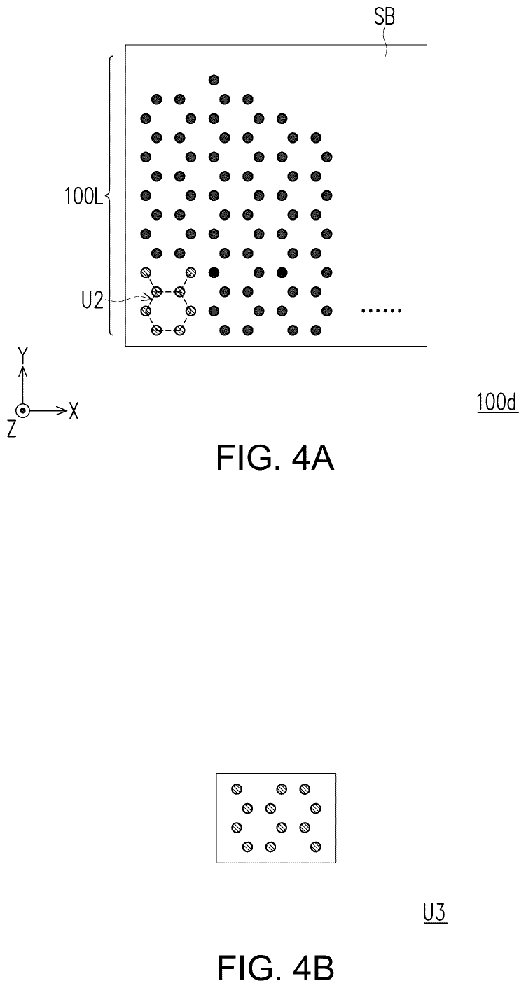

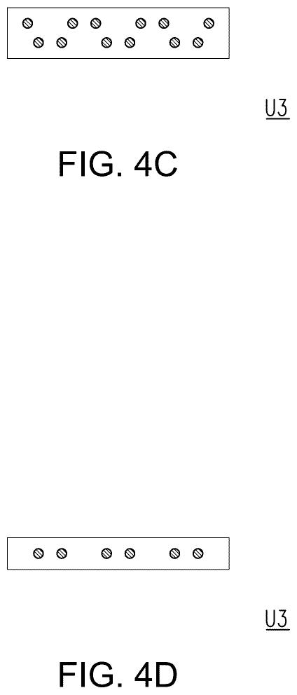

FIG. 4A is a schematic top view of a target substrate according to the fourth embodiment of the present disclosure, which shows a schematic top view of a unit in the first embodiment of the target substrate. FIG. 4B is a schematic top view of the unit in the second embodiment of the target substrate of FIG. 4A. FIG. 4C is a schematic top view of the unit in the third embodiment of the target substrate of FIG. 4A. FIG. 4D is a schematic top view of the unit in the fourth embodiment of the target substrate of FIG. 4A. It should be noted that the embodiments of FIG. 4A to FIG. 4D may adopt the component numbers and part of the content of the embodiments of FIG. 3A to FIG. 3D, wherein the same or similar numbers are adopted to represent the same or similar components, and descriptions of the same technical content are omitted.

Please refer to FIG. 4A. The main difference between the target substrate 100d and the target substrate 100c is that the target locations 100L are staggered in the direction Y, and the adjacent target locations 100L in the direction X are mirror-disposed.

In this embodiment, the unit U3 made up of the plurality of target locations 100L may be, for example, the patterns shown in FIG. 4A to FIG. 4D, but the disclosure is not limited thereto.

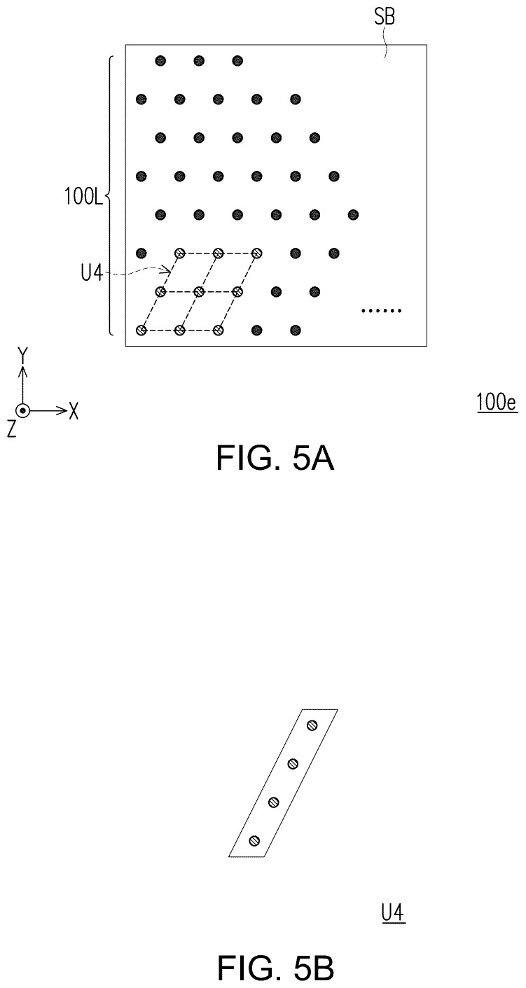

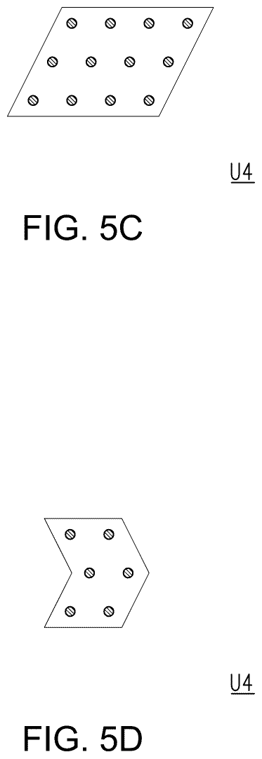

FIG. 5A is a schematic top view of a target substrate according to the fifth embodiment of the present disclosure, which shows a schematic top view of a unit in the first embodiment of the target substrate. FIG. 5B is a schematic top view of the unit in the second embodiment of the target substrate of FIG. 5A. FIG. 5C is a schematic top view of the unit in the third embodiment of the target substrate of FIG. 5A. FIG. 5D is a schematic top view of the unit in the fourth embodiment of the target substrate of FIG. 5A. It should be noted that the embodiments of FIG. 5A to FIG. 5D may adopt the component numbers and part of the content of the embodiments of FIG. 3A to FIG. 3D, wherein the same or similar numbers are adopted to represent the same or similar components, and descriptions of the same technical content are omitted.

Please refer to FIG. 5A. The main difference between the target substrate 100e and the target substrate 100c is that the target locations 100L are staggered in the direction Y, and adjacent target locations 100L in the direction X have substantially equal distances therebetween.

In this embodiment, the unit U4 made up of the plurality of target locations 100L may be, for example, the patterns shown in FIG. 5A to FIG. 5D, but the disclosure is not limited thereto.

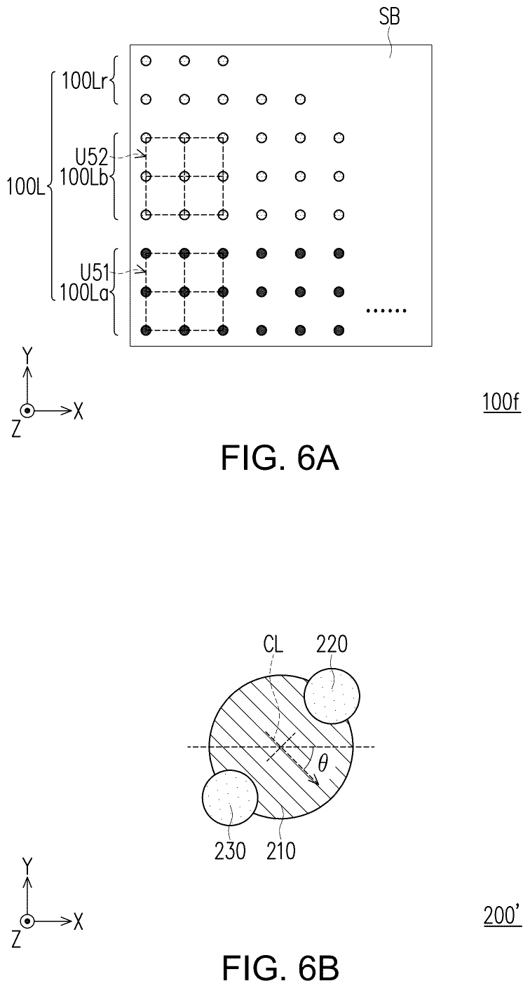

FIG. 6A is a schematic top view of a target substrate according to the sixth embodiment of the present disclosure, and FIG. 6B is a top view of a target object according to another embodiment of the present disclosure. It should be noted that the embodiments of FIG. 6A to FIG. 6B may adopt the component numbers and part of the content of the embodiments of FIG. 3A and FIG. 1B, wherein the same or similar numbers are adopted to represent the same or similar components, and descriptions of the same technical content are omitted.

Referring to FIG. 6A, the main difference between the target substrate 100f and the target substrate 100c is that the target object on the target substrate 100f has different rotation angles θ.

The distribution of target object 200 in this embodiment satisfies translational symmetry, but may be divided into sets with multiple different rotation angles θ. Therefore, multiple different units may be found on the target substrate 100c, and each of which is made up of the plurality of target locations 100L.

In this embodiment, the distribution of the target object 200 has the following relationships:

$$\begin{matrix}{Die}_{A} ∈ {Unit}_{A} ; \\ {Die}_{B} ∈ {Unit}_{B} ; \\ {Unit}_{A} ( {r}_{o} + R ) = {Unit}_{A} ( {r}_{o} ) ; \\ {Unit}_{B} ( {r}_{o} + R ) = {Unit}_{B} ( {r}_{o} ) ,\end{matrix}$$

wherein Die_{A} is the target object 200 having the first rotation angle, Die_{B} is the target object 200 having the second rotation angle, Unit_{A} is the first unit made up of a plurality of target locations 100L, Units is the second unit made up of a plurality of target locations 100L, rₒ is the starting locations of the first unit and the second unit respectively, and R is the translation amounts of the first unit and the second unit respectively.

In detail, please refer to FIG. 6B. FIG. 6B shows the target object 200′, whose rotation angle θ is different from that of the target object 200, wherein the rotation angle θ of the target object 200 is 45 degrees, and the rotation angle θ of the target object 200′ is −45 degrees. Under the circumstances, the unit U51 made up of the plurality of target locations 100La and the unit U52 made up of the plurality of target locations 100Lb may be found on the target substrate 100f. Please refer to FIG. 6C, which shows that the unit U51 is a rectangular pattern made up of 3×3 target locations 100La, and the unit U52 is a rectangular pattern made up of 3×3 target locations 100Lb. Based on the above, the target object 200 may be disposed on the unit transfer stamp (not shown) in the form of the above-mentioned unit U51, and the target object 200′ may be disposed on the unit transfer stamp in the form of the above-mentioned unit U52. Subsequently, the unit transfer stamp may be utilized to transfer 3×3 target objects 200 and target objects 200′ respectively to the unit U51 and the unit U52 recurring on the target substrate 100c, thereby improving the efficiency of transferring the target object 200 to the target substrate 100f.

Through the description of the above embodiments, the method of transferring the target object 200 and the target object 200′ to the target substrate 100f in this embodiment includes the following steps.
Step (1′): A plurality of units U51 and a plurality of units U52 recurring on the target substrate 100f are defined. One of the plurality of units U51 is made up of the plurality of target locations 100La on the target substrate 100f, and one of the plurality of units U52 is made up of the plurality of target locations 100Lb on the target substrate 100f.
Step (2a): The plurality of target objects 200 are disposed on the unit transfer stamp, wherein the plurality of target objects 200 on the unit transfer stamp correspond to the plurality of target locations 100La.
Step (3a): The unit transfer stamp is utilized to transfer the plurality of target objects 200 to the target substrate 100f.

In this step, the first group of target objects 200 may be transferred to the first region (a region including one unit U51) on the target substrate 100f using the unit transfer stamp, and then the unit transfer stamp is moved in the direction X and/or direction Y. After the unit transfer stamp is attached to the second group of target objects 200, the unit transfer stamp is utilized to transfer the second group of target objects 200 to the second region (a region including another unit U51) on the target substrate 100f. However, the disclosure is not limited thereto.
Step (2b): The plurality of target objects 200′ are disposed on another unit transfer stamp, wherein the plurality of target objects 200′ on another unit transfer stamp correspond to the plurality of target locations 100Lb.
Step (3b): The unit transfer stamp is utilized to transfer the plurality of target objects 200′ to the target substrate 100f.

In this step, the first group of target objects 200′ may be transferred to the third region (a region including one unit U52) on the target substrate 100f using the unit transfer stamp, and then the unit transfer stamp is moved in the direction X and/or the direction Y. After the unit transfer stamp is attached to the second group of target objects 200′, the unit transfer stamp is utilized to transfer the second group of target objects 200′ to the fourth region (a region including another unit U52) on the target substrate 100f. However, this disclosure is not limited thereto.
Step (4′): The at least one target object 200 and/or the at least one target object 200′ is transferred to the remaining target locations of the target substrate 100f.

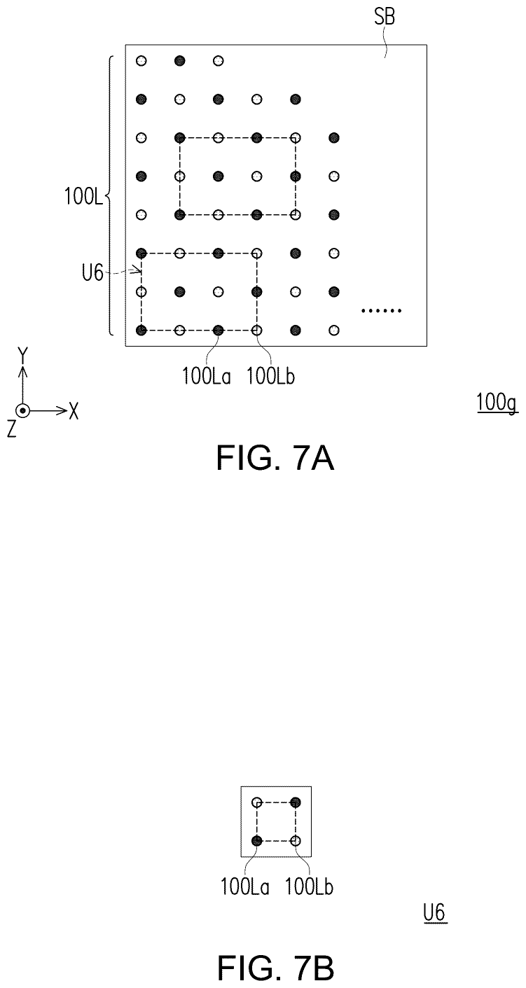

FIG. 7A is a schematic top view of a target substrate according to the seventh embodiment of the present disclosure, which shows a schematic top view of a unit in the first embodiment of the target substrate, and FIG. 7B is a schematic top view of the unit in the second embodiment of the target substrate of FIG. 7A. It should be noted that the embodiments of FIG. 7A and FIG. 7B may respectively adopt the component numbers and part of the content of the embodiments of FIG. 3A to FIG. 3D, wherein the same or similar numbers are used to represent the same or similar elements, and description of the same technical content is omitted.

Referring to FIG. 7A, the main difference between the target substrate 100g and the target substrate 100f is that the target locations 100La and target locations 100Lb on the target substrate 100g are staggered with each other.

In detail, in this embodiment, the target location adjacent to the target location 100La is the target location 100Lb, and vice versa. In this case, a unit U6 is made up of a plurality of target locations 100La and a plurality of target locations 100Lb staggered with each other may be found on the target substrate 100g. Please continue to refer to FIG. 7A, which shows that the unit U6 is a rectangular pattern made up of 4×3 two target locations 100La and two target locations 100Lb staggered with each other. Based on the above, the target object 200 and the target object 200′ may be disposed on the unit transfer stamp (not shown) in the form of the above-mentioned unit U6. Subsequently, 4×3 target objects 200 may be transferred to the unit U6 recurring on the target substrate 100g through the unit transfer stamp, thereby improving the efficiency of transferring the target object 200 to the target substrate 100g.

However, this disclosure does not limit that the unit U6 is made up of 4×3 six target locations 100La and six target locations 100Lb staggered with each other. Referring to FIG. 7B, the unit U6 may be, for example, a rectangular pattern made up of 2×2 two target locations 100La and two target locations 100Lb staggered with each other.

To sum up, in some embodiments of the present disclosure, by defining a recurring unit made up of a plurality of target locations on the target substrate, and disposing the target object on the unit transfer stamp in the form of units, it is possible to improve the efficiency of transferring the target object to the target substrate.

Furthermore, in other embodiments of the present disclosure, the above-mentioned recurring units may include multiple groups of units that are different from each other. By defining different units, the efficiency of transferring the target object to the target substrate may also be improved.

What is claimed is:

1. A method of transferring a target object to a target substrate, comprising:
defining a plurality of units recurring on the target substrate, wherein one of the plurality of units is made up of a plurality of target locations on the target substrate;
disposing a plurality of the target objects on a unit transfer stamp, wherein the plurality of target objects on the unit transfer stamp correspond to the plurality of target locations;
transferring the plurality of target objects to the target substrate using the unit transfer stamp; and
transferring at least one of the target objects to remaining target locations on the target substrate.

2. The method of transferring the target object to the target substrate according to claim 1, wherein the step of transferring the plurality of target objects to the target substrate using the unit transfer stamp comprises:
transferring a first group of target objects to a first region on the target substrate using the unit transfer stamp;
moving the unit transfer stamp in a first direction and/or a second direction; and
transferring a second group of target objects to a second region on the target substrate using the unit transfer stamp;
wherein the first direction is different from the second direction.

3. The method of transferring the target object to the target substrate according to claim 2, wherein the first group of target objects and the second group of target objects have different sizes and/or shapes.

4. The method of transferring the target object to the target substrate according to claim 1, wherein the step of transferring the plurality of target objects to the target substrate using the unit transfer stamp comprises:
transferring a first group of target objects to a first region on the target substrate using the unit transfer stamp;
rotating the unit transfer stamp; and
transferring a second group of target objects to a second region on the target substrate using the unit transfer stamp.

5. The method of transferring the target object to the target substrate according to claim 4, wherein the first group of target objects and the second group of target objects have different sizes and/or shapes.

6. The method of transferring the target object to the target substrate according to claim 1, wherein each of the plurality of target objects comprises the same chip.

7. The method of transferring the target object to the target substrate according to claim 1, wherein each of the plurality of target objects comprises different chips.

8. The method of transferring the target object to the target substrate according to claim 1, wherein shapes of the plurality of target objects comprise circles, rectangles, hexagons or polygons.

9. The method of transferring the target object to the target substrate according to claim 1, wherein at least one of the plurality of target objects comprises a control element.

10. The method of transferring the target object to the target substrate according to claim 1, wherein a distribution of the plurality of target objects has the following relationships:
$$\begin{matrix}{Die}_{A} ∈ {Unit}_{A} ; \\ {Unit}_{A} ( {r}_{o} + R ) = {Unit}_{A} ( {r}_{o} ) ,\end{matrix}$$
wherein Die_{A} is the plurality of target objects, Unit_{A} is one of the plurality of units, rₒ is a starting location of the one of the plurality of units, and R is a translation amount of the one of the plurality of units.

11. A method of transferring a target object to a target substrate, comprising:
defining a plurality of first units and a plurality of second units recurring on the target substrate, wherein one of the plurality of first units is made up of a plurality of first target locations on the target substrate, and one of the plurality of second units is made up of a plurality of second target locations on the target substrate;
disposing a plurality of the target objects on a first unit transfer stamp, wherein the plurality of target objects on the first unit transfer stamp correspond to the plurality of first target locations;
transferring the plurality of target objects to the target substrate using the first unit transfer stamp;
disposing the plurality of target objects on a second unit transfer stamp, wherein the plurality of target objects on the second unit transfer stamp correspond to the plurality of second target locations; and
transferring the plurality of target objects to the target substrate using the second unit transfer stamp.

12. The method of transferring the target object to the target substrate according to claim 11, further comprising transferring at least one of the target objects to remaining target locations on the target substrate.

13. The method of transferring the target object to the target substrate according to claim 11, wherein the step of transferring the plurality of target objects to the target substrate using the first unit transfer stamp comprises:
transferring a first group of target objects to a first region on the target substrate using the first unit transfer stamp;
moving the first unit transfer stamp in a first direction and/or a second direction; and
transferring a second group of target objects to a second region on the target substrate using the first unit transfer stamp;
wherein the first direction is different from the second direction.

14. The method of transferring the target object to the target substrate according to claim 13, wherein the first group of target objects and the second group of target objects have different sizes and/or shapes.

15. The method of transferring the target object to the target substrate according to claim 11, wherein the step of transferring the plurality of target objects to the target substrate using the first unit transfer stamp comprises:
transferring a first group of target objects to a first region on the target substrate using the first unit transfer stamp;
rotating the first unit transfer stamp; and
transferring a second group of target objects to a second region on the target substrate using the first unit transfer stamp.

16. The method of transferring the target object to the target substrate according to claim 15, wherein the first group of target objects and the second group of target objects have different sizes and/or shapes.

17. The method of transferring the target object to the target substrate according to claim 11, wherein each of the plurality of target objects comprises the same chip.

18. The method of transferring the target object to the target substrate according to claim 11, wherein each of the plurality of target objects comprises different chips.

19. The method of transferring the target object to the target substrate according to claim 11, wherein shapes of the plurality of target objects comprise circles, rectangles, hexagons or polygons.

20. The method of transferring the target object to the target substrate according to claim 11, wherein a distribution of the plurality of target objects has the following relationships:
$$\begin{matrix}{Die}_{A} ∈ {Unit}_{A} ; \\ {Die}_{B} ∈ {Unit}_{B} ; \\ {Unit}_{A} ( {r}_{o} + R ) = {Unit}_{A} ( {r}_{o} ) ; \\ {Unit}_{B} ( {r}_{o} + R ) = {Unit}_{B} ( {r}_{o} ) ,\end{matrix}$$
wherein Die_{A} is the plurality of target objects having a first rotation angle, Die_{B} is the plurality of target objects having a second rotation angle, Unit_{A} is one of the plurality of first units, Units is one of the plurality of second units, rₒ is starting locations of the one of the plurality of first units and the one of the plurality of second units respectively, and R is translation amounts of the one of the plurality of first units and the one of the plurality of second units respectively.
